(19) United States
(12) Patent Application Publication
(10) Pub. No.: US 2026/0271712 A1
(43) Pub. Date: Sep. 10, 2026

(54) SEMICONDUCTOR DEVICE

(71) Applicant: Mitsubishi Electric Corporation, Tokyo (JP)

(72) Inventor: Taketo NISHIYAMA, Tokyo (JP)

(73) Assignee: Mitsubishi Electric Corporation, Tokyo (JP)

(21) Appl. No.: 19/437,157

(22) Filed: Dec. 30, 2025

(30) Foreign Application Priority Data
Mar. 6, 2025 (JP) 2025-035644

(51) Int. Cl. H10W 40/20; H10W 40/60; H10W 76/12

(52) U.S. Cl. CPC H10W 40/235; H10W 40/242; H10W 76/161; H10W 40/611

(57) ABSTRACT

A semiconductor device according to the present disclosure includes: a semiconductor module having a heatsink plate placed on the lower surface side; a heatsink having the semiconductor module mounted on the upper surface; a heat dissipating material interposed between the heatsink plate and the heatsink; and a spacer placed between the semiconductor module and the heatsink. In the semiconductor device, the spacer is placed on the outer side of the heat dissipating material in a planar view.

### BACKGROUND

### Technical Field

The present disclosure relates to a semiconductor device.

### Description of the Background Art

There is a known conventional technique by which a heat dissipating material such as a heat dissipating sheet or grease is interposed between a heatsink and a semiconductor module to dissipate heat generated by the semiconductor module.

Structures of a conventional semiconductor module and a conventional heatsink are disclosed in Japanese Patent Application Laid-Open No. 2023-129, for example. Japanese Patent Application Laid-Open No. 2023-129 discloses a semiconductor device that includes a semiconductor module having a heatsink plate (a base plate), and a heatsink on which the semiconductor module is mounted. Also, thermally conductive grease as a heat dissipating material is interposed between the heatsink plate provided on the lower surface of the semiconductor module and the heatsink.

In the conventional technique, during an operation of the semiconductor module, the heatsink plate is deformed due to a temperature rise, and pumping out occurs. The pumping out is a phenomenon in which a heat dissipating material between the heatsink plate and the heatsink is pushed out due to the deformation. Further, when the semiconductor module is stopped, the heat dissipating material pushed out to the periphery of the semiconductor module absorbs the outside air and contracts. As a result, voids are formed in the heat dissipating material. Therefore, the thermal resistance of the semiconductor module increases, and the heat dissipation properties of the semiconductor module are degraded, which is a problem.

### SUMMARY

An object of the present disclosure is to provide a semiconductor device capable of reducing the pumping out of a heat dissipating material, and reducing the increase in thermal resistance and the degradation in heat dissipation properties of a semiconductor module.

A semiconductor device of the present disclosure includes a semiconductor module, a heatsink, a heat dissipating material, and a spacer. The semiconductor module has the heatsink plate provided on the lower surface side. The heatsink has the semiconductor module mounted on the upper surface. The heat dissipating material is interposed between the heatsink plate and the heatsink. The spacer is placed between the semiconductor module and the heatsink. The spacer is placed on the outer side of the heat dissipating material in a planar view.

With a semiconductor device according to the present disclosure, it is possible to provide a semiconductor device capable of reducing pumping out of a heat dissipating material, and reducing an increase in thermal resistance and degradation in heat dissipation properties of a semiconductor module.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic cross-sectional view of a semiconductor device according to a first preferred embodiment;

FIG. 2 is a schematic plan view of the semiconductor device according to the first preferred embodiment;

FIG. 3 is a schematic cross-sectional view of a semiconductor device according to the first preferred embodiment, illustrating a state in which the semiconductor device shown in FIGS. 1 and 2 is mounted on a heatsink;

FIGS. 4A and 4B are a schematic cross-sectional view and a schematic plan view of a semiconductor device at a time when a semiconductor module according to conventional technique is attached to a heatsink;

FIGS. 5A and 5B are a schematic cross-sectional view and a schematic plan view of the semiconductor device at a time when the semiconductor module according to the conventional technique has started operating;

FIGS. 6A and 6B are a schematic cross-sectional view and a schematic plan view of the semiconductor device at a time when the semiconductor module according to the conventional technique is stopped;

FIGS. 7A and 7B are a schematic cross-sectional view and a schematic plan view of the semiconductor device at a time when a semiconductor module according to the first preferred embodiment is attached to the heatsink;

FIGS. 8A and 8B are a schematic cross-sectional view and a schematic plan view of the semiconductor device at a time when the semiconductor module according to the first preferred embodiment has started operating;

FIG. 9 is an enlarged view of a region A in FIG. 8A of the semiconductor device at a time when the semiconductor module according to the first preferred embodiment has started operating;

FIGS. 10A and 10B are a schematic cross-sectional view and a schematic plan view of the semiconductor device at a time when the semiconductor module according to the first preferred embodiment is stopped;

FIG. 11 is a graph showing the change in the temperature of the semiconductor module according to the first preferred embodiment at a time when the semiconductor module has started and stopped operating;

FIG. 12 is a schematic cross-sectional view of a semiconductor device according to a first modification of the first preferred embodiment;

FIG. 13 is a schematic cross-sectional view of a semiconductor device according to a second modification of the first preferred embodiment;

FIG. 14 is a schematic plan view of a semiconductor device according to a second preferred embodiment;

FIGS. 15A and 15B are a schematic cross-sectional view and a schematic plan view of the semiconductor device at a time when a semiconductor module according to the second preferred embodiment is attached to the heatsink;

FIGS. 16A and 16B are a schematic cross-sectional view and a schematic plan view of the semiconductor device at a time when the semiconductor module according to the second preferred embodiment has started operating;

FIGS. 17A and 17B are a schematic cross-sectional view and a schematic plan view of the semiconductor device at a time when the semiconductor module according to the second preferred embodiment is stopped;

FIGS. 18A and 18B are a schematic cross-sectional view and a schematic plan view of a semiconductor device at a time when a semiconductor module according to the first preferred embodiment is stopped;

FIG. 19 is a schematic cross-sectional view of a semiconductor device according to a third preferred embodiment;

FIG. 20 is a schematic plan view of the semiconductor device according to the third preferred embodiment;

FIGS. 21A and 21B are a schematic cross-sectional view and a schematic plan view of the semiconductor device at a time when a semiconductor module according to the third preferred embodiment is attached to a heatsink;

FIGS. 22A and 22B are a schematic cross-sectional view and a schematic plan view of the semiconductor device at a time when the semiconductor module according to the third preferred embodiment has started operating; and

FIGS. 23A and 23B are a schematic cross-sectional view and a schematic plan view of the semiconductor device at a time when the semiconductor module according to the third preferred embodiment is stopped.

### DESCRIPTION OF THE PREFERRED EMBODIMENTS

### Introduction

One side in a direction parallel to the depth direction of a semiconductor device is referred to as the “upper” side, and the other side is referred to as the “lower” side. One of the two main surfaces of a substrate, a layer, or some other member is referred to as the upper surface, and the other surface is referred to as the lower surface. The “upper” and “lower” directions are not necessarily directions based on gravity or the directions at the time of mounting the semiconductor device.

Further, in the description below, for ease of explanation, the depth direction of a semiconductor device is referred to as the X-axis direction, the width direction of the semiconductor device intersecting the X-axis direction is referred to as the Y-axis direction, and the thickness direction or the height direction of the semiconductor device, which is the normal direction with respect to the X-Y plane, is referred to as the Z-axis direction.

Also, the drawings are schematically illustrated, and mutual relationships between sizes and positions of images shown in different drawings are not necessarily accurately shown, and can be changed as appropriate. Furthermore, in the description below, the same components are denoted by the same reference signs, and names and functions thereof are also the same. Therefore, detailed explanation thereof will be omitted in some cases.

### First Preferred Embodiment.

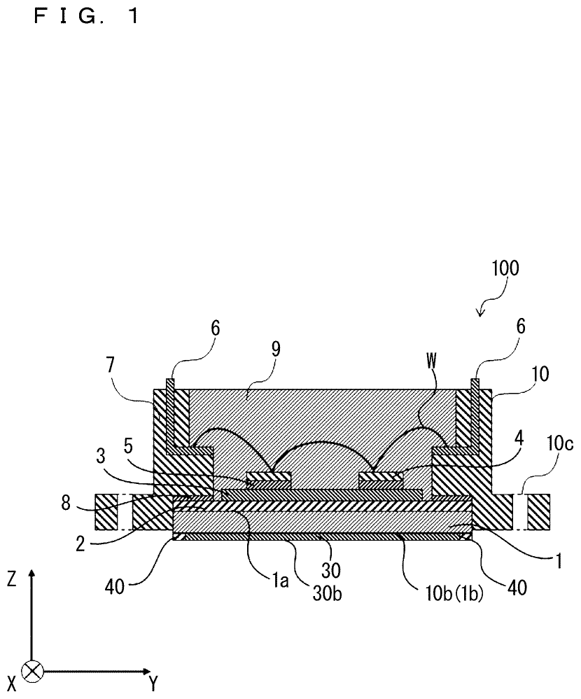

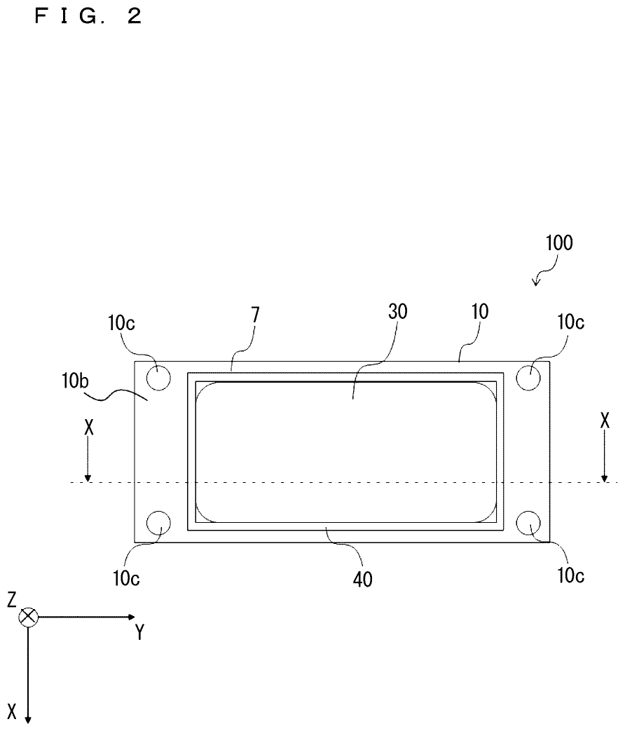

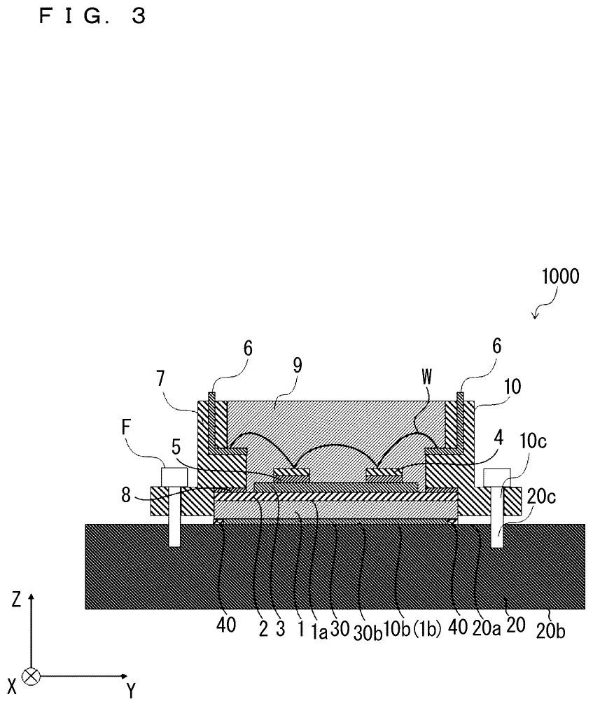

A first preferred embodiment is described below, with reference to the drawings. FIG. 1 is a schematic cross-sectional view of a semiconductor device 100 according to the first preferred embodiment. FIG. 2 is a schematic plan view of the semiconductor device 100 according to the first preferred embodiment. Note that FIG. 1 shows a cross-section taken along a dot-and-dash line X-X defined in FIG. 2. Note that, in FIG. 1, fastening portions 10c are indicated by dotted lines. Also, FIG. 2 is a horizontal cross-sectional view, taken along a lower surface 30b of a heat dissipating material 30 of the semiconductor device 100 shown in FIG. 1. Note that, in the following description of the present invention, a “plan view” is a horizontal cross-sectional view taken along the lower surface 30b of the heat dissipating material 30 of the semiconductor device as in FIG. 2. Also, in the following description of the present invention, a “planar view” is a viewpoint of viewing a cross-sectional surface from below, the cross-sectional surface being the lower surface 30b of the heat dissipating material 30 of the semiconductor device as illustrated in FIG. 2. Further, FIG. 3 is a schematic cross-sectional view of a semiconductor device 1000, illustrating a state in which the semiconductor device 100 shown in FIGS. 1 and 2 is mounted on the heatsink 20.

Referring to FIGS. 1 to 3, the configurations of the semiconductor devices 100 and 1000 are described. As illustrated in FIGS. 1 and 2, the semiconductor device 100 is a semiconductor device mounted on the heatsink 20, and includes a semiconductor module 10 having a heatsink plate 1, a heat dissipating material 30 provided on the lower surface 1b of the heatsink plate 1, and a spacer 40 provided on the semiconductor module 10. The spacer 40 is provided on the outer side of the heat dissipating material 30 in a planar view.

As illustrated in FIG. 3, the semiconductor device 1000 includes the semiconductor module 10, the heatsink 20 on which the semiconductor module 10 is mounted, the heat dissipating material 30 interposed between the heatsink plate 1 of the semiconductor module 10 and the heatsink 20, and the spacer 40 provided between the semiconductor module 10 and the heatsink 20, and the spacer 40 is provided on the outer side of the heat dissipating material 30 in a planar view.

First, a detailed example configuration of the semiconductor module 10 is described with reference to FIGS. 1 to 3. The semiconductor module 10 includes the heatsink plate 1.

The heatsink plate 1 is formed with a material having electrical conductivity and thermal conductivity. The heatsink plate 1 is formed with a metal material such as copper or aluminum, for example.

As illustrated in FIGS. 1 and 3, an insulating substrate 2 is provided on the upper surface 1a of the heatsink plate 1. The insulating substrate 2 is mounted on the upper surface 1a of the heatsink plate 1 with solders or the like, for example. The insulating substrate 2 is formed with a resin having insulating properties, such as ceramic, for example.

As illustrated in FIGS. 1 and 3, a metal pattern 3 is provided on the upper surface of the insulating substrate 2. The metal pattern 3 is formed with a highly conductive metal such as copper.

As illustrated in FIGS. 1 and 3, semiconductor elements 4 are mounted on the metal pattern 3 via solders 5. Also, as illustrated in FIGS. 1 and 3, the semiconductor elements 4 are joined to terminals 6 via wires W, for example. The semiconductor elements 4 may be formed with Si, or may be formed with SiC, GaN, or Ga2O3, which is a wide bandgap semiconductor. Note that the device type of the semiconductor elements 4 is not necessarily limited to a particular one, but may be switching elements such as insulated gate bipolar transistors (IGBTs) or metal oxide semiconductor field effect transistors (MOSFETs), or may be freewheeling elements.

Further, as illustrated in FIGS. 1 to 3, the semiconductor module 10 may have a case member 7 on its outer periphery. The case member 7 is formed with a resin having insulating properties, and is joined to the heatsink plate 1. Also, as illustrated in FIG. 2, the case member 7 may be provided so as to surround the outer periphery of the insulating substrate 2 or the like disposed on the heatsink plate 1. Further, as illustrated in FIGS. 1 and 3, the case member 7 may be bonded to the insulating substrate 2 with an adhesive 8.

Also, as illustrated in FIGS. 1 to 3, fastening portions 10c are provided in the semiconductor module 10. As illustrated in FIGS. 1 to 3, in the present preferred embodiment, the fastening portions 10c are provided in the case member 7. As illustrated in FIG. 3, fastening members F for fastening the semiconductor module 10 to the heatsink 20 are inserted into and attached to the fastening portions 10c. Further, as illustrated in FIG. 2, the fastening portions 10c are preferably provided at the four corners of the outer periphery of the semiconductor module 10.

Further, as illustrated in FIGS. 1 and 3, the semiconductor module 10 may be sealed with a sealing material 9. As illustrated in FIG. 1, in the present preferred embodiment, the sealing material 9 is disposed on the inner side of the case member 7. The sealing material 9 is formed with gel, resin, or the like having insulating properties, for example.

The semiconductor module 10 is designed as described above. Note that the fastening portions 10c on the side of the semiconductor module 10 may be provided on the heatsink plate 1.

Next, the heat dissipating material 30 is described with reference to FIGS. 1 to 3. In the case of the semiconductor device 100, the heat dissipating material 30 is provided on the lower surface 1b of the heatsink plate 1, as illustrated in FIGS. 1 and 2. Further, in the case of the semiconductor device 1000, the heat dissipating material 30 is provided so as to be interposed between the heatsink plate 1 of the semiconductor module 10 and the heatsink 20, as illustrated in FIG. 3. The heat dissipating material 30 is formed with a material that has a high thermal conductivity and has flexibility. The heat dissipating material 30 is formed with a thermal interface material (TIM) such as thermal grease, thermal putty, or a thermal sheet, for example. Note that the thickness of the heat dissipating material 30 is about 10 μm to 100 μm in the case of a thermal sheet, and the amount of application is about 50 μm to 100 μm in the case of thermal grease. The heat dissipating material 30 is only required to be provided at least immediately below the heatsink plate 1, and is not necessarily provided immediately below the case member 7.

Next, the spacer 40 is described with reference to FIGS. 1 to 3. In the case of the semiconductor device 100, the spacer 40 is provided on the semiconductor module 10, as illustrated in FIGS. 1 and 2. Note that, in the case of the semiconductor device 100, the spacer 40 may be provided so as to be in contact with the lower surface 10b of the semiconductor module 10, as illustrated in FIGS. 1 and 2. In the present preferred embodiment, the spacer 40 is provided so as to be in contact with the lower surface 1b of the heatsink plate 1 in the semiconductor module 10, as illustrated in FIGS. 1 and 2. In the case of the semiconductor device 1000, the spacer 40 is disposed between the semiconductor module 10 and the heatsink 20, as illustrated in FIG. 3.

As illustrated in FIG. 2, the spacer 40 is preferably provided so as to surround the heat dissipating material 30 in a planar view, and, as illustrated in FIG. 2, the spacer 40 may be provided in a rectangular shape in a planar view. Note that it is preferable that the spacer 40 is continuously provided in a circumferential direction so as to surround the heat dissipating material 30 in a planar view, as illustrated in FIG. 2. However, the spacer 40 may be provided in the form of dots at intervals, not continuously formed in the circumferential direction so as to surround the heat dissipating material 30, in a planar view. Further, as illustrated in FIG. 3, the spacer 40 is preferably provided so as to be in contact with the lower surface of the semiconductor module 10 and the upper surface of the heatsink 20, and the spacer 40 is preferably formed with an adhesive that cures at a temperature equal to or higher than the heat-generating temperature of the semiconductor module 10.

Next, the heatsink 20 is described with reference to FIG. 3. As illustrated in FIG. 3, the heatsink 20 has an upper surface 20a on which the semiconductor module 10 is mounted via the heat dissipating material 30. Note that the heatsink 20 is formed with a metal having a high thermal conductivity, such as aluminum. Also, in the heatsink 20, a fin may be formed on the side of a lower surface 20b. Further, the heatsink 20 has fastening portions 20c to which the fastening members F for being fastened to the semiconductor module 10 are attached.

As described above, the semiconductor module 10 and the heatsink 20 have the fastening portions 10c and 20c, respectively, and the fastening members F are inserted into the respective fastening portions 10c and 20c, so that the semiconductor module 10 and the heatsink 20 are fastened to each other by the fastening members F. Note that the fastening portions 10c may be screw holes, and the fastening members F may be screws, nuts, or the like. Further, as described above, the respective fastening portions 10c are preferably provided at the four corners of the outer periphery, but may be provided at least at two or more locations, and may be selected as appropriate depending on the size or the like of the semiconductor device. Note that the fastening members F may be inserted from the side of the lower surface 20b of the heatsink 20.

The semiconductor devices 100 and 1000 of the present preferred embodiment are formed as described above. Like the semiconductor device 100 of the present preferred embodiment, a semiconductor device is mounted on the heatsink 20 and includes the semiconductor module 10 having the heatsink plate 1, the heat dissipating material 30 provided on the lower surface 1b of the heatsink plate 1, and the spacer 40 provided on the semiconductor module 10, and the spacer 40 is provided on the outer side of the heat dissipating material 30 in a planar view. With this configuration, when the semiconductor device 100 is mounted on the heatsink 20, and the semiconductor module 10 has started operating, the pumping out of the heat dissipating material 30 can be reduced, and the increase in thermal resistance and the degradation in heat dissipation properties of the semiconductor module 10 can be reduced. Also, like the semiconductor device 1000 of the present preferred embodiment, a semiconductor device includes the semiconductor module 10 having the heatsink plate 1, the heatsink 20 on which the semiconductor module 10 is mounted, the heat dissipating material 30 interposed between the heatsink plate 1 and the heatsink 20, and the spacer 40 provided between the semiconductor module 10 and the heatsink 20, and the spacer 40 is provided on the outer side of the heat dissipating material 30 in a planar view. Thus, when the semiconductor module 10 has started operating, the pumping out of the heat dissipating material 30 can be reduced, and the increase in thermal resistance and the degradation in heat dissipation properties of the semiconductor module 10 can be reduced. The reason for this is described below.

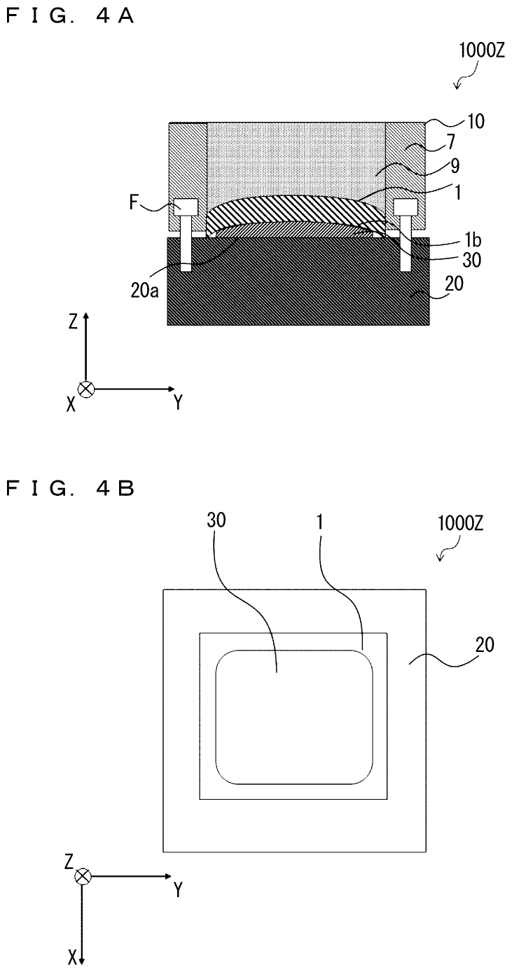

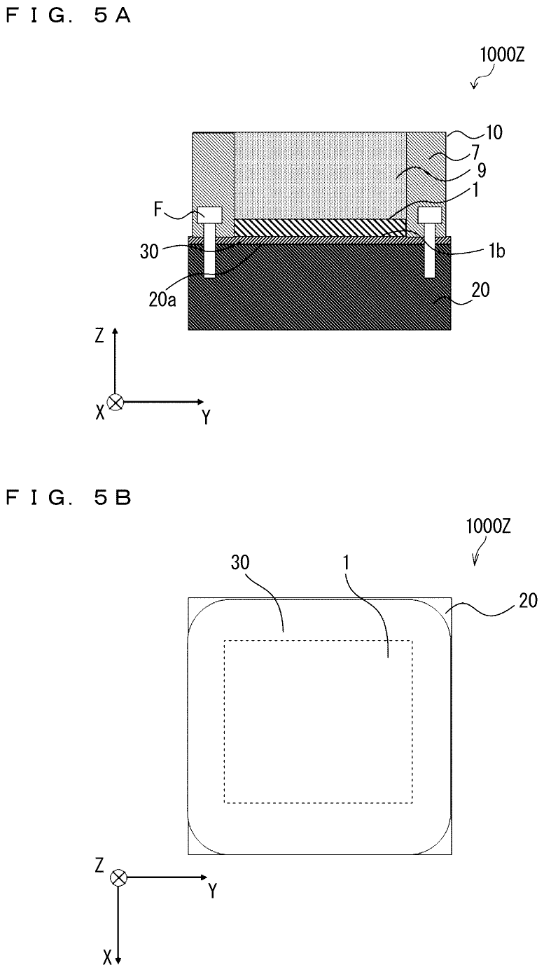

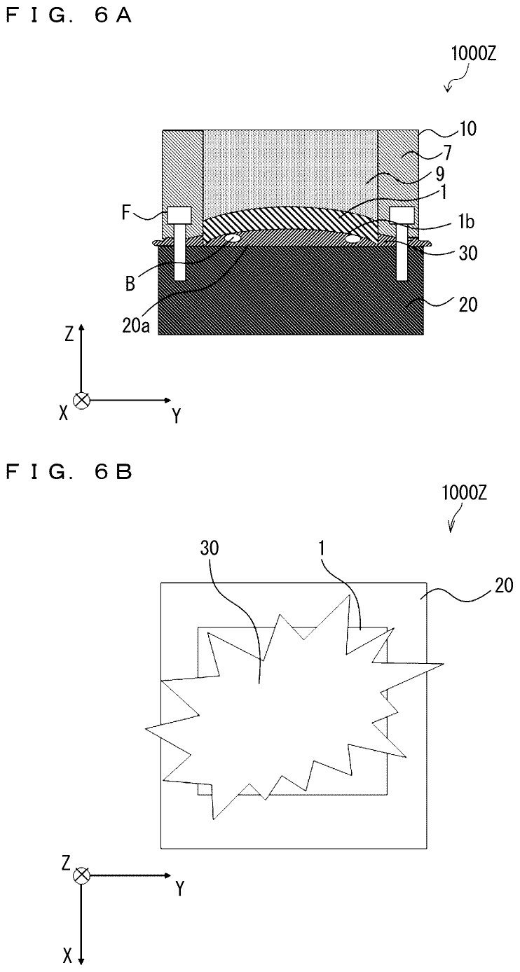

First, for comparison with the semiconductor devices 100 and 1000 according to the present preferred embodiment, a semiconductor device 1000Z according to a conventional technique is shown as a comparative example in FIGS. 4A to 6B. FIGS. 4A and 4B are a schematic cross-sectional view and a schematic plan view of the semiconductor device 1000Z at a time when a semiconductor module 10 according to the conventional technique is attached to a heatsink 20. FIGS. 5A and 5B are a schematic cross-sectional view and a schematic plan view of the semiconductor device 1000Z at a time when the semiconductor module 10 according to the conventional technique has started operating. FIGS. 6A and 6B are a schematic cross-sectional view and a schematic plan view of the semiconductor device 1000Z at a time when the semiconductor module 10 according to the conventional technique is stopped. Note that, for ease of illustration, some elements of the semiconductor module 10 are not shown in the drawings. Also, among FIGS. 4A to 6B, each drawing with “A” is a cross-sectional view, and each drawing with “B” is a plan view.

In general, the lower surface 1b of the heatsink plate 1, which is the heat dissipating surface of the semiconductor module 10, is often designed and managed in a convex form with respect to the upper surface 20a of the heatsink 20 to reduce the thermal resistance between the heatsink plate 1 and the heatsink 20. However, as illustrated in FIGS. 4A and 4B, when the semiconductor module 10 is attached to the heatsink 20, the lower surface 1b of the heatsink plate 1 is deformed so as to warp in a direction away from the upper surface 20a of the heatsink 20.

As the semiconductor elements 4 are heated during an operation of the semiconductor module 10, the lower surface 1b of the heatsink plate 1 is deformed in a direction toward the upper surface 20a of the heatsink 20 as illustrated in FIGS. 5A and 5B. With the deformation of the heatsink plate 1 and the thermal expansion of the heat dissipating material 30, the heat dissipating material 30 interposed between the heatsink plate 1 and the heatsink 20 is pushed out to the periphery of the semiconductor device 1000Z, and thus, pumping out occurs.

As the semiconductor elements 4 are cooled when the semiconductor module 10 is stopped, the lower surface 1b of the heatsink plate 1 is deformed in a direction away from the upper surface 20a of the heatsink 20 as illustrated in FIGS. 6A and 6B. With the deformation of the heatsink plate 1 and the contraction of the heat dissipating material 30 interposed between the heatsink plate 1 and the heatsink 20, the heat dissipating material 30 pushed out to the periphery of the semiconductor device 1000Z absorbs the outside air, and thus, voids B appear in the heat dissipating material 30 as illustrated in FIG. 6A. Because the voids B appear in the heat dissipating material 30, the thermal resistance of the semiconductor module 10 increases, and the heat dissipation properties are degraded.

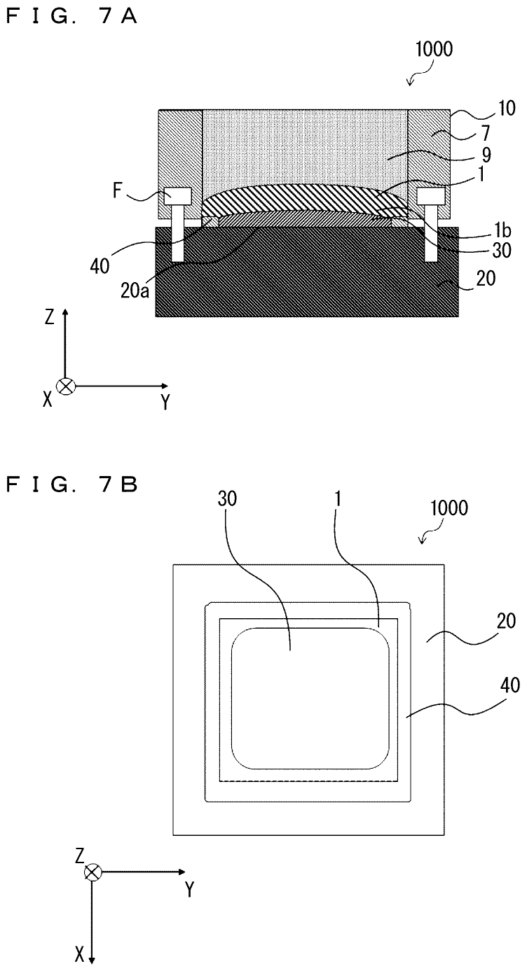

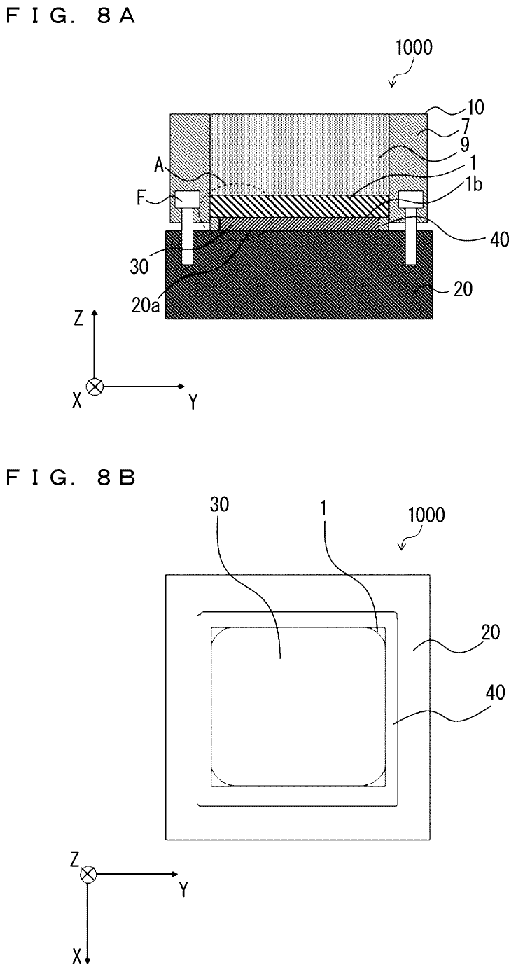

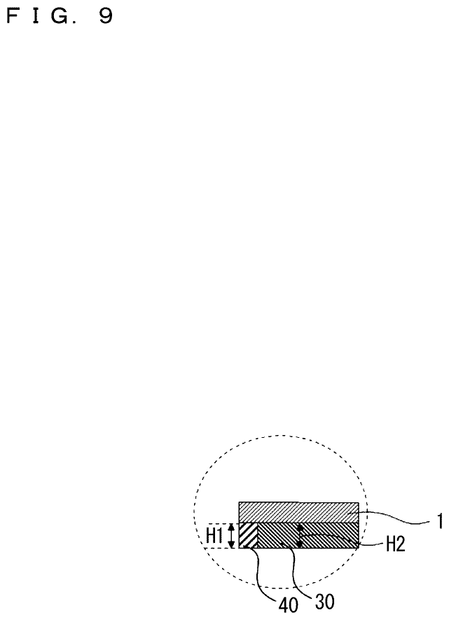

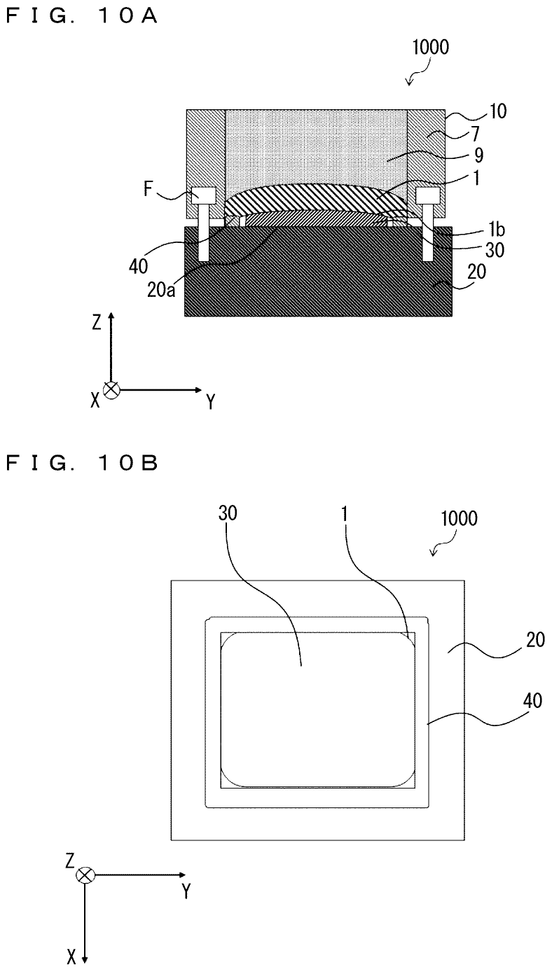

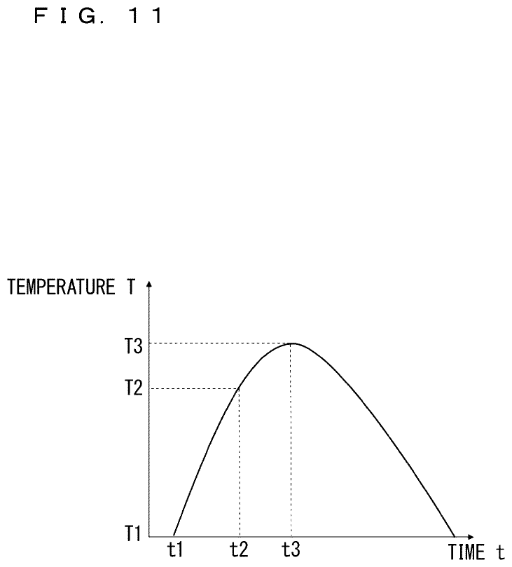

Next, the semiconductor device 1000 according to the present preferred embodiment is described with reference to FIGS. 7A to 11. FIGS. 7A and 7B are a schematic cross-sectional view and a schematic plan view of the semiconductor device 1000 at a time when the semiconductor module 10 according to the first preferred embodiment is attached to the heatsink 20. FIGS. 8A and 8B are a schematic cross-sectional view and a schematic plan view of the semiconductor device 1000 at a time when the semiconductor module 10 according to the first preferred embodiment has started operating. FIG. 9 is an enlarged view of a region A in FIG. 8A of the semiconductor device 1000 at a time when the semiconductor module 10 according to the first preferred embodiment has started operating. FIGS. 10A and 10B are a schematic cross-sectional view and a schematic plan view of the semiconductor device 1000 at a time when the semiconductor module 10 according to the first preferred embodiment is stopped. Also, among FIGS. 7A and 7B, 8A and 8B, and 10A and 10B, each drawing with “A” is a cross-sectional view, and each drawing with “B” is a plan view. Note that, for ease of illustration, some elements of the semiconductor module 10 are not shown in each cross-sectional view A, and the heatsink 20 is additionally shown in each plan view B. Further, in FIGS. 7A to 10B, the spacer 40 is shown as being formed with an adhesive that cures at a temperature equal to or higher than the heat-generating temperature of the semiconductor module 10. FIG. 11 is a graph showing the changes in the temperature of the semiconductor module 10 when the semiconductor module 10 has started and stopped operating in the case where the spacer 40 is formed with an adhesive that cures at a temperature equal to or higher than the heat-generating temperature of the semiconductor module 10. In FIG. 11, the time t when the semiconductor module 10 started operating is represented by t1, and the temperature T of the semiconductor module 10 at t1 is represented by T1. Also, in FIG. 11, the time t when the adhesive as the spacer 40 cures is represented by t2, and the temperature T of the semiconductor module 10 at t2 is represented by T2. T2 represents the curing temperature that is the temperature at which the adhesive as the spacer 40 cures. Further, in FIG. 11, the time t when the semiconductor module 10 is stopped is represented by t3, and the temperature T of the semiconductor module 10 at t3 is represented by T3.

As illustrated in FIGS. 7A and 7B, when the semiconductor module 10 is attached to the heatsink 20, the lower surface 1b of the heatsink plate 1 is deformed so as to warp in a direction away from the upper surface 20a of the heatsink 20, as in FIGS. 4A and 4B.

As illustrated in FIGS. 8A and 8B, when the semiconductor module 10 is operating, the lower surface 1b of the heatsink plate 1 is deformed in a direction toward the upper surface 20a of the heatsink 20, as in FIGS. 5A and 5B. As illustrated in FIGS. 8A and 8B, in conjunction with the deformation of the heatsink plate 1 and the thermal expansion of the heat dissipating material 30, the heat dissipating material 30 wets and spreads in an outer circumferential direction. As illustrated in FIGS. 8A and 8B, in the semiconductor device 1000 of the first preferred embodiment, the spacer 40 is provided on the outer side of the heat dissipating material 30 in a planar view. Accordingly, even in a case where the heatsink plate 1 is deformed during an operation of the semiconductor module 10, the spacer 40 functions as a stopper. Thus, the heat dissipating material 30 interposed between the heatsink plate 1 and the heatsink 20 can be prevented from moving to the outer side of the spacer 40, and the pumping out by which the heat dissipating material 30 is pushed out to the periphery of the semiconductor device 1000 can be reduced.

Also, in the case where the spacer 40 is provided so as to surround the heat dissipating material 30 in a planar view, the heat dissipating material 30 interposed between the heatsink plate 1 and the heatsink 20 can be more effectively prevented from moving to the outer side of the spacer 40, and the occurrence of pumping out by which the heat dissipating material 30 is pushed out to the periphery of the semiconductor device 1000 can be further reduced.

Further, in the case where the spacer 40 is provided so as to be in contact with the lower surface 10b of the semiconductor module 10 and the upper surface 20a of the heatsink 20, the heat dissipating material 30 interposed between the heatsink plate 1 and the heatsink 20 can be more effectively prevented from moving to the outer side of the spacer 40, and the occurrence of pumping out by which the heat dissipating material 30 is pushed out to the periphery of the semiconductor device 1000 can be further reduced.

Also, in the case where the spacer 40 is formed with an adhesive that cures at a temperature equal to or higher than the heat-generating temperature of the semiconductor module 10, even when the heatsink plate 1 is deformed during an operation of the semiconductor module 10, the spacer 40 does not cure and has fluidity at time t1≤t<t2. Therefore, the spacer 40 is deformed following the deformation of the heatsink plate 1, and cures at time t=t2. Accordingly, in the case where the spacer 40 is formed with an adhesive that cures at a temperature equal to or higher than the heat-generating temperature of the semiconductor module 10, even when the heatsink plate 1 is deformed, the adhesive can be always in contact with the lower surface 1b of the heatsink plate 1 and the upper surface 20a of the heatsink 20. Thus, the heat dissipating material 30 interposed between the heatsink plate 1 and the heatsink 20 can be more effectively prevented from moving to the outer side of the spacer 40, and the occurrence of pumping out by which the heat dissipating material 30 is pushed out to the periphery of the semiconductor device 1000 can be further reduced. Further, as illustrated in FIG. 9, in a state where the semiconductor module 10 is generating heat, and the adhesive as the spacer 40 has cured, the height H1 of the adhesive and the height H2 of the heat dissipating material 30 are preferably the same. For example, compared with those in a case where H1>H2, in the case where H1=H2, it is possible to prevent the heat dissipating material 30 from having a portion not in contact with the semiconductor module 10 or the heatsink 20, and it is possible to further reduce the increase in thermal resistance and the degradation in heat dissipation properties of the semiconductor module 10. Also, compared with those in a case where H1<H2, in the case where H1=H2, it is possible to prevent bending of the heat dissipating material 30 by the heat dissipating member 30, and reduce the appearance of cracks in the insulating substrate 2 due to bending stress. Note that, to satisfy H1=H2, the timing at which the adhesive cures and the timing at which the heat dissipating material 30 wets and spreads in the outer circumferential direction should be matched, for example, at the time of heat generation of the semiconductor module 10 (time t2).

As illustrated in FIGS. 10A and 10B, when the semiconductor module 10 is stopped, the lower surface 1b of the heatsink plate 1 is deformed so as to warp in a direction away from the upper surface 20a of the heatsink 20, as in FIGS. 6A and 6B. As described above, during an operation of the semiconductor module 10, the occurrence of pumping out by which the heat dissipating material 30 is pushed out to the periphery of the semiconductor device 1000 with the spacer 40 can be reduced. Thus, even in a case where the heatsink plate 1 is deformed and the heat dissipating material 30 interposed between the heatsink plate 1 and the heatsink 20 contracts when the semiconductor module 10 is stopped, the appearance of the voids B in the heat dissipating material 30 can be reduced. Accordingly, the increase in thermal resistance and the degradation in heat dissipation properties of the semiconductor module 10 can be reduced.

Next, methods of manufacturing the semiconductor devices 100 and 1000 according to the present preferred embodiment are described. The methods of manufacturing the semiconductor devices 100 and 1000 according to the present preferred embodiment are basically the same as a conventional method of manufacturing a semiconductor device, except for the spacer forming process. Therefore, explanation of the process of forming the semiconductor module 10 will be omitted from the following description.

First, the method of manufacturing the semiconductor device 100 is described. The method of manufacturing the semiconductor device 100 includes a heat-dissipating-material forming process and a spacer forming process.

First, the heat-dissipating-material forming process is described. In the heat-dissipating-material forming process, the heat dissipating material 30 is formed on at least the lower surface 1b of the heatsink plate 1 in the semiconductor module 10. Thermal grease may be applied onto the lower surface 1b of the heatsink plate 1, or a thermal sheet may be attached to the lower surface 1b of the heatsink plate 1.

Next, the spacer forming process is described. In the spacer forming process, the spacer 40 is formed on the lower surface 10b of the semiconductor module 10 at a portion on the outer side of the heat dissipating material 30 in a planar view. Here, as for an example method of forming the spacer 40, a case where the spacer 40 is an adhesive that cures at a temperature equal to or higher than the heat-generating temperature of the semiconductor module 10 is described. In the present preferred embodiment, the adhesive as the spacer 40 is applied onto the lower surface 1b of the heatsink plate 1 so as to surround the heat dissipating material 30 in a planar view.

Through the above processes, the semiconductor device 100 is manufactured. As described above, the method of manufacturing the semiconductor device 100 according to the present preferred embodiment further includes the spacer forming process, and the spacer 40 is formed on the lower surface 10b of the semiconductor module 10 at a portion on the outer side of the heat dissipating material 30 in a planar view. As the spacer 40 is formed as described above, when the semiconductor device 100 is mounted on the heatsink 20 and the semiconductor module 10 has started operating, the pumping out of the heat dissipating material 30 can be reduced, and the increase in thermal resistance and the degradation in heat dissipation properties of the semiconductor module 10 can be reduced.

Next, the method of manufacturing the semiconductor device 1000 is described. The method of manufacturing the semiconductor device 1000 includes a heat-dissipating-material forming process, a spacer forming process, and a fastening process.

First, the heat-dissipating-material forming process is described. In the heat-dissipating-material forming process, the heat dissipating material 30 is formed on the lower surface 1b of the heatsink plate 1 of the semiconductor module 10 or the upper surface 20a of the heatsink 20.

Next, the spacer forming process is described. In the spacer forming process, the spacer 40 is formed on the lower surface 10b of the semiconductor module 10 or the upper surface 20a of the heatsink 20 at a portion on the outer side of the heat dissipating material 30 in a planar view. Here, as for an example method of forming the spacer 40, a case where the spacer 40 is an adhesive that cures at a temperature equal to or higher than the heat-generating temperature of the semiconductor module 10 is described. In the present preferred embodiment, the adhesive as the spacer 40 is applied onto the lower surface 1b of the heatsink plate 1 or the upper surface 20a of the heatsink 20 so as to surround the heat dissipating material 30 in a planar view. Note that the spacer forming process may be performed after the heat-dissipating-material forming process, and the heat-dissipating-material forming process may be performed after the spacer forming process.

Next, the fastening process is described. In the fastening process, the semiconductor module 10 is first mounted on the heatsink 20 via the heat dissipating material 30. Next, the fastening members F are inserted into the fastening portions 10c provided in the semiconductor module 10 and the heatsink 20. The heatsink 20 and the semiconductor module 10 are then fastened to each other by the fastening members F. In this manner, the semiconductor module 10, the heatsink 20, and the heat dissipating material 30 can be brought into close contact with one another.

Through the above processes, the semiconductor device 1000 is manufactured. As described above, the method of manufacturing the semiconductor device 1000 according to the present preferred embodiment further includes the spacer forming process, and the spacer 40 is formed on the lower surface 10b of the semiconductor module 10 or the upper surface 20a of the heatsink 20 at a portion on the outer side of the heat dissipating material 30 in a planar view. As the spacer 40 is formed as described above, when the semiconductor module 10 has started operating, the pumping out of the heat dissipating material 30 can be reduced, and the increase in thermal resistance and the degradation in heat dissipation properties of the semiconductor module 10 can be reduced.

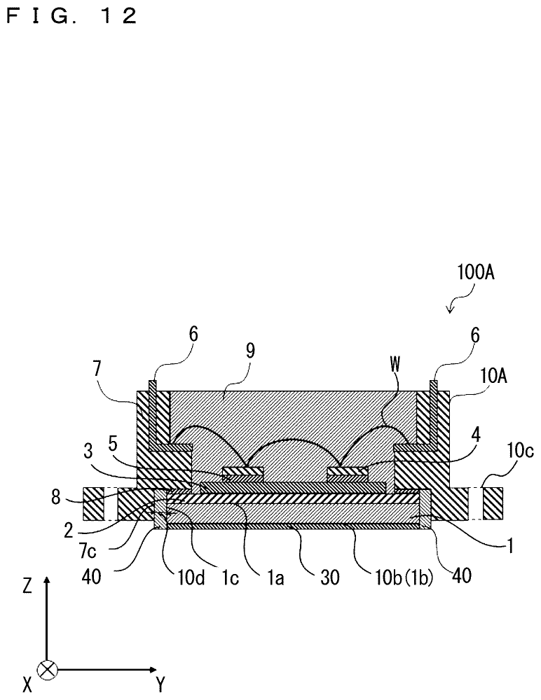

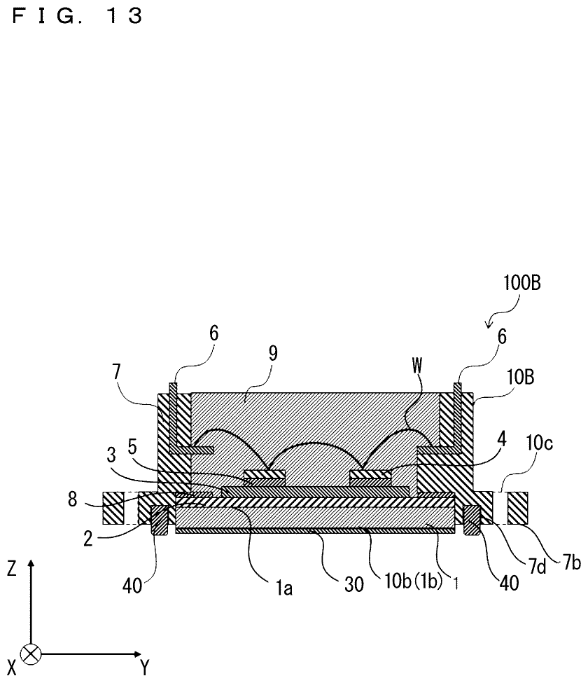

Next, modifications of the first preferred embodiment are described with reference to FIGS. 12 and 13. First, a first modification is described with reference to FIG. 12. FIG. 12 is a schematic cross-sectional view of a semiconductor device 100A according to the first modification. Note that, in FIG. 12, the fastening portions 10c are indicated by dotted lines.

As illustrated in FIG. 12, in the semiconductor device 100A of the first modification, the spacer 40 is provided so as to be in contact with the case member 7. Note that, as illustrated in FIG. 12, in semiconductor device 100A of the first modification, a semiconductor module 10A has gap 10d between the case member 7 and side surfaces 1c of the heatsink plate 1, and the spacer 40 is placed in the gap 10d. Note that the gap 10d and the spacer 40 are preferably provided so as to surround the heat dissipating material 30 in a planar view. Also, the spacer 40 is preferably formed with an adhesive that cures at a temperature equal to or higher than the heat-generating temperature of the semiconductor module 10A. Further, in a state where the semiconductor module 10A is generating heat, and the adhesive as the spacer 40 has cured, the height H1 of the adhesive and the height H2 of the heat dissipating material 30 are preferably the same. In a case where the adhesive is provided as illustrated in FIG. 12, the height H1 of the adhesive is the height from the height of the lower surface 1b of the heatsink plate 1 to the height of the upper surface 20a of the heatsink 20.

The semiconductor device 100A of the first modification can achieve the same effects as those of the semiconductor device 100 of the first preferred embodiment. Furthermore, in the semiconductor device 100A of the first modification, the spacer 40 is placed in the gap 10d. Accordingly, in a case where the spacer 40 is formed with an adhesive that cures at a temperature equal to or higher than the heat-generating temperature of the semiconductor module 10A, for example, the spacer 40 can be easily formed, and thus, semiconductor device productivity can be increased.

Next, a second modification is described with reference to FIG. 13. FIG. 13 is a schematic cross-sectional view of a semiconductor device 100B according to the second modification. Note that, in FIG. 13, the fastening portions 10c are indicated by dotted lines.

As illustrated in FIG. 13, in the semiconductor device 100B of the second modification, the spacer 40 is provided so as to be in contact with the case member 7, as in the first modification. Note that, as illustrated in FIG. 13, in semiconductor device 100B of the second modification, the case member 7 of a semiconductor module 10B has a recessed portion 7d in its lower surface 7b, and the spacer 40 is placed in the recessed portion 7d. Note that the recessed portion 7d and the spacer 40 are preferably provided so as to surround the heat dissipating material 30 in a planar view. Also, the spacer 40 is preferably formed with an adhesive that cures at a temperature equal to or higher than the heat-generating temperature of the semiconductor module 10B. Further, in a state where the semiconductor module 10B is generating heat, and the adhesive as the spacer 40 has cured, the height H1 of the adhesive and the height H2 of the heat dissipating material 30 are preferably the same. In a case where the adhesive is provided as illustrated in FIG. 13, the height H1 of the adhesive is the height from the height of the lower surface 1b of the heatsink plate 1 to the height of the upper surface 20a of the heatsink 20.

The semiconductor device 100B of the second modification can achieve the same effects as those of the semiconductor device 100 of the first preferred embodiment. Furthermore, in the semiconductor device 100B of the second modification, the spacer 40 is placed in the recessed portion 7d. Accordingly, in a case where the spacer 40 is formed with an adhesive that cures at a temperature equal to or higher than the heat-generating temperature of the semiconductor module 10B, for example, the spacer 40 can be easily formed, and thus, semiconductor device productivity can be increased.

### Second Preferred Embodiment.

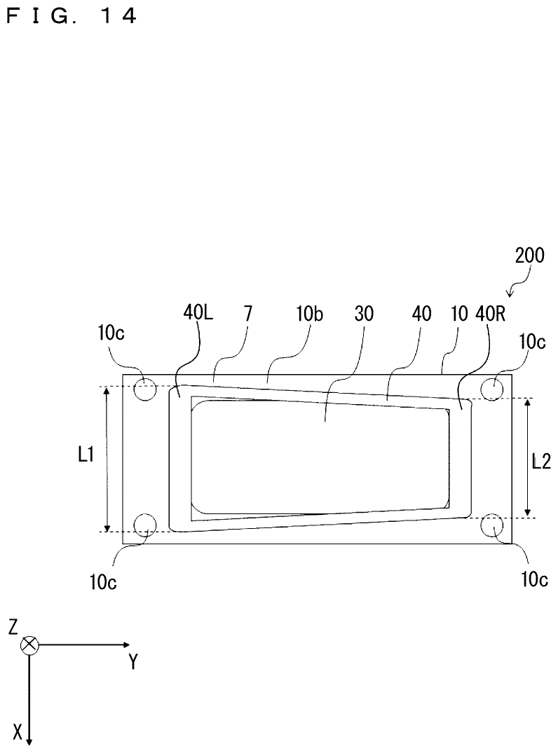

A semiconductor device 200 according to a second preferred embodiment is now described, with reference to FIG. 14. FIG. 14 is a schematic plan view of the semiconductor device 200 according to the second preferred embodiment. Note that the semiconductor device 200 of the second preferred embodiment is assumed to be mounted in a vertical direction. Note that a schematic cross-sectional view of the semiconductor device 200 is assumed to be the same as that shown in FIG. 1, and therefore, is not shown. Also, a schematic cross-sectional view of the semiconductor device 2000 that shows a state in which the semiconductor device 200 shown in FIG. 14 is mounted on a heatsink 20 is assumed to be the same as that shown in FIG. 3, and therefore, is not shown.

As illustrated in FIG. 14, in the semiconductor device 200 according to the second preferred embodiment, a spacer 40 is provided in a trapezoidal shape so as to surround a heat dissipating material 30 in a planar view. Note that, in FIG. 14, of the spacer 40, the length L1 of a left portion 40L located on the left side (the negative side in the Y-axis direction) in FIG. 14 is greater than the length L2 of a right portion 40R located on the right side (the positive side in the Y-axis direction) in FIG. 14. In this case, it is assumed that, at the time of mounting, the semiconductor device 2000 is mounted so that the left portion 40L of the spacer 40 is located on the upper side in the direction of gravitational force, and the right portion 40R of the spacer 40 is located on the lower side in the direction of gravitational force. The reason for that will be described later. Note that the spacer 40 may be provided on the lower surface 1b of the heatsink plate 1, or on the lower surface 7b of the case member 7.

Like the semiconductor device 1000, the semiconductor device 2000 includes a heatsink 20 and fastening members F.

The semiconductor devices 200 and 2000 of the second preferred embodiment are designed as described above. Like the semiconductor device 100 according to the first preferred embodiment, the semiconductor device 200 according to the second preferred embodiment has a configuration in which the spacer 40 is provided on the semiconductor module 10 at a portion on the outer side of the heat dissipating material 30 in a planar view. Thus, when the semiconductor device 200 is mounted on the heatsink 20, and the semiconductor module 10 has started operating, the heat dissipating material 30 interposed between the heatsink plate 1 and the heatsink 20 can be more effectively prevented from moving to the outer side of the spacer 40, the pumping out by which the heat dissipating material 30 is pushed out to the periphery of the semiconductor device 2000 can be reduced, and the increase in thermal resistance and the degradation in heat dissipation properties of the semiconductor module 10 can be reduced. Also, like the semiconductor device 1000 according to the first preferred embodiment, the semiconductor device 2000 according to the second preferred embodiment has a configuration in which the spacer 40 is provided on the outer side of the heat dissipating material 30 in a planar view, between the semiconductor module 10 and the heatsink 20. Thus, when the semiconductor module 10 has started operating, the pumping out of the heat dissipating material 30 can be reduced, and the increase in thermal resistance and the degradation in heat dissipation properties of the semiconductor module 10 can be reduced.

Further, in the semiconductor devices 200 and 2000 according to the second preferred embodiment, a spacer 40 is provided in a trapezoidal shape so as to surround the heat dissipating material 30 in a planar view. With this arrangement, the amount of shrinkage to be observed at a time when the heat dissipating material 30 contracts can be reduced when the semiconductor module 10 is stopped. The reason for that is described below.

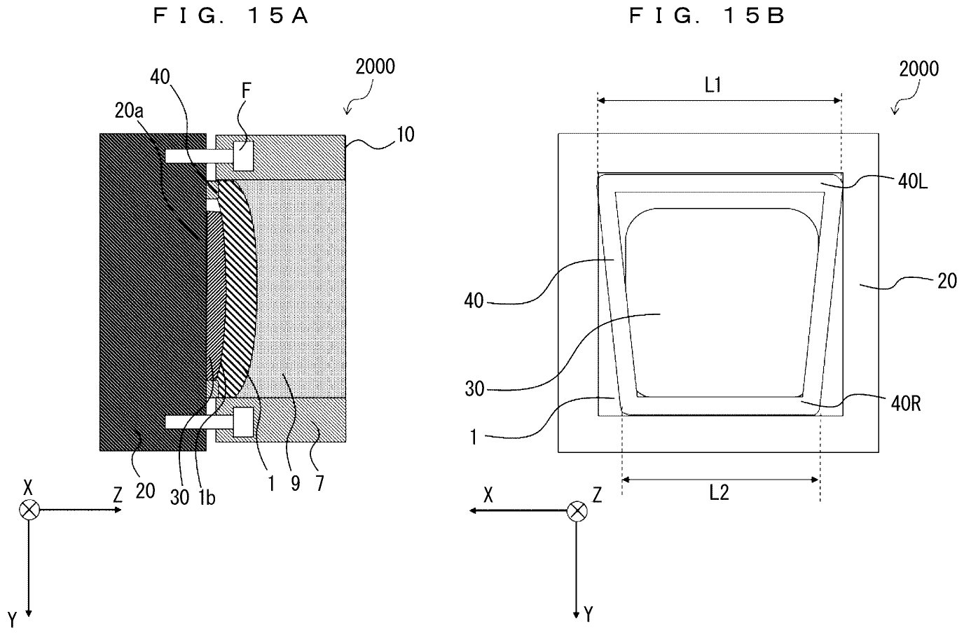

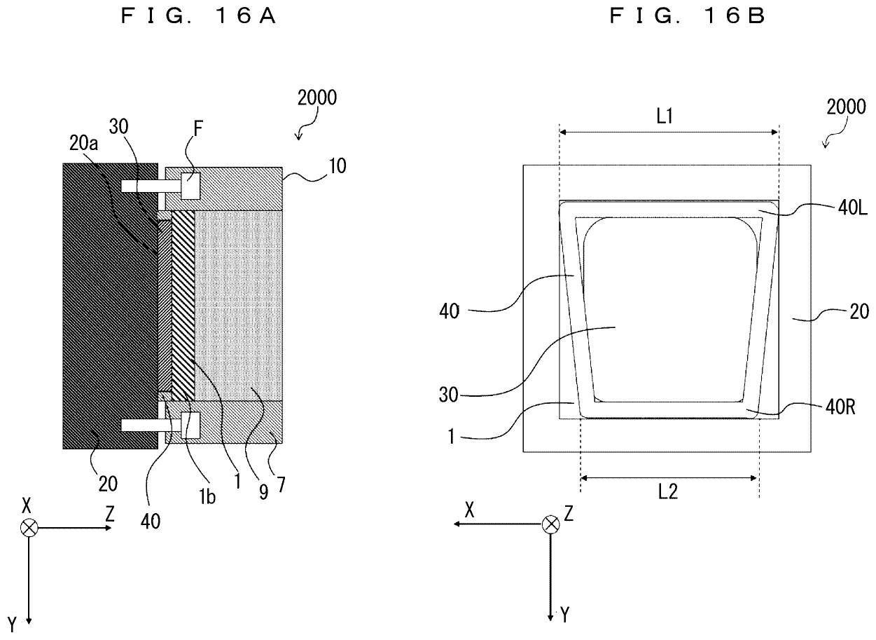

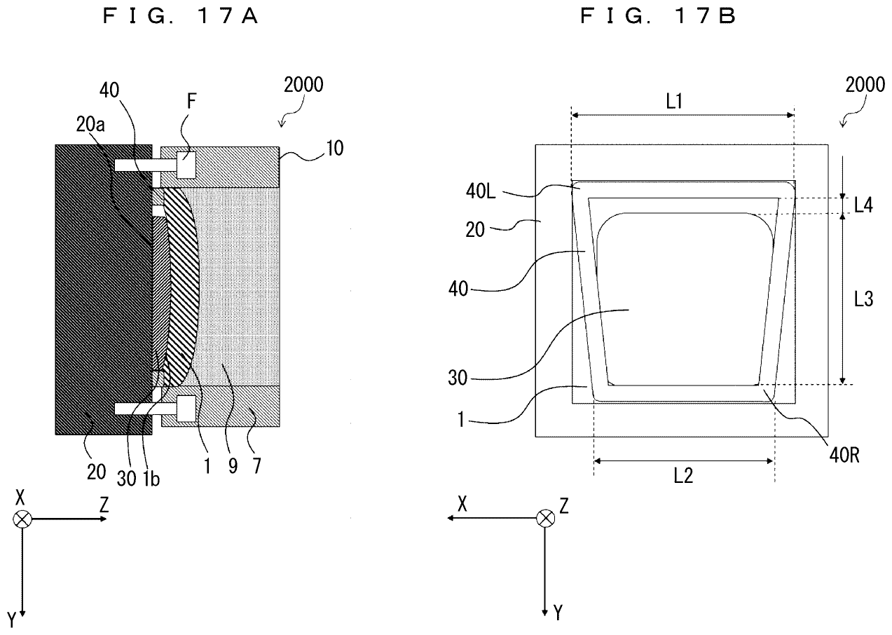

FIGS. 15A to 17B illustrate the semiconductor device 2000 according to the present preferred embodiment. FIGS. 15A and 15B are a schematic cross-sectional view and a schematic plan view of the semiconductor device 2000 at a time when the semiconductor module 10 according to the second preferred embodiment is attached to the heatsink 20. FIGS. 16A and 16B are a schematic cross-sectional view and a schematic plan view of the semiconductor device 2000 at a time when the semiconductor module 10 according to the second preferred embodiment has started operating. FIGS. 17A and 17B are a schematic cross-sectional view and a schematic plan view of the semiconductor device 2000 at a time when the semiconductor module 10 according to the second preferred embodiment is stopped. Also, among FIGS. 15A to 17B, each drawing with “A” is a cross-sectional view, and each drawing with “B” is a plan view. Note that, for ease of illustration, some elements of the semiconductor module 10 are not shown in each cross-sectional view A, and the heatsink 20 is additionally shown in each plan view B. Further, in FIGS. 15A to 17B, the heat dissipating material 30 is a member having fluidity, such as thermal grease or thermal putty. Further, referring to FIGS. 15A to 17B, the spacer 40 is described as a spacer formed with an adhesive that cures at a temperature equal to or higher than the heat-generating temperature of the semiconductor module 10. Note that FIGS. 15A to 17B illustrate a state in which the semiconductor device 2000 is mounted in a vertical direction. That is, these drawings illustrate a state in which the semiconductor device 2000 is mounted so that the left portion 40L of the spacer 40 is located on the upper side in the direction of gravitational force (the negative side in the Y-axis direction in FIGS. 15A to 17B), and the right portion 40R of the spacer 40 is located on the lower side in the direction of gravitational force (the positive side in the Y-axis direction in FIGS. 15A to 17B). In the following description, it is simply referred to as “mounted in the vertical direction”. Note that, in FIG. 17B, the height of the heat dissipating material 30 at a time when the semiconductor module 10 according to the second preferred embodiment is stopped and the heat dissipating material 30 contracts is represented by L3, and the amount of shrinkage of the heat dissipating material 30 is represented by L4.

As illustrated in FIGS. 15A and 15B, when the semiconductor module 10 is attached to the heatsink 20, the lower surface 1b of the heatsink plate 1 is deformed so as to warp in a direction away from the upper surface 20a of the heatsink 20, as in FIGS. 7A and 7B. Note that, as the semiconductor device 2000 is mounted in the vertical direction, and the heat dissipating material 30 has fluidity, the heat dissipating material 30 flows to the lower side in the direction of gravitational force (the positive side in the Y-axis direction in FIGS. 15A and 15B), as illustrated in FIGS. 15A and 15B.

As illustrated in FIGS. 16A and 16B, during an operation of the semiconductor module 10, the lower surface 1b of the heatsink plate 1 is deformed so as to warp in a direction toward the upper surface 20a of the heatsink 20, as in FIGS. 8A and 8B. As illustrated in FIGS. 16A and 16B, with the deformation of the heatsink plate 1 and the thermal expansion of the heat dissipating material 30, the heat dissipating material 30 flows so as to wet and spread to the upper side in the direction of gravitational force (the negative side in the Y-axis direction in FIGS. 16A and 16B). Note that, as illustrated in FIGS. 16A and 16B, in the semiconductor device 2000 of the second preferred embodiment, the spacer 40 is provided on the outer side of the heat dissipating material 30 in a planar view. Accordingly, even in a case where the heatsink plate 1 is deformed during an operation of the semiconductor module 10, the spacer 40 functions as a stopper. Thus, the heat dissipating material 30 interposed between the heatsink plate 1 and the heatsink 20 can be prevented from moving to the outer side of the spacer 40, and the pumping out by which the heat dissipating material 30 is pushed out to the periphery of the semiconductor device 2000 can be reduced.

As illustrated in FIGS. 17A and 17B, when the semiconductor module 10 is stopped, the lower surface 1b of the heatsink plate 1 is deformed so as to warp in a direction away from the upper surface 20a of the heatsink 20, as in FIGS. 10A and 10B. As illustrated in FIGS. 17A and 17B, with the deformation of the heatsink plate 1 and the contraction of the heat dissipating material 30, the heat dissipating material 30 flows so as to contract on the lower side in the direction of gravitational force (the positive side in the Y-axis direction in FIGS. 17A and 17B).

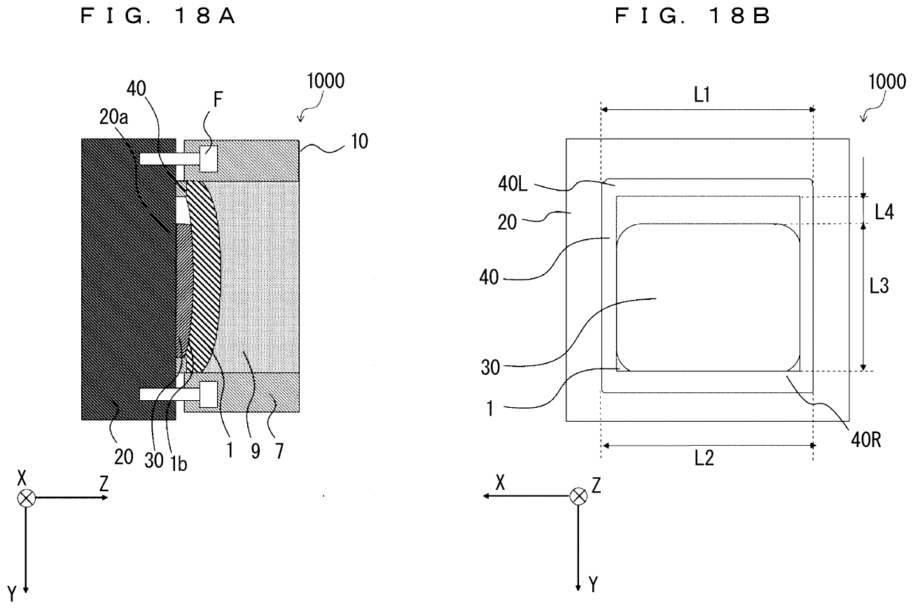

Here, as a comparative example of the semiconductor device 2000, a state in which the semiconductor device 1000 is mounted in the vertical direction, and the semiconductor module 10 is stopped is illustrated in FIGS. 18A and 18B. FIGS. 18A and 18B are a schematic cross-sectional view and a schematic plan view of the semiconductor device 1000 at a time when the semiconductor module 10 according to the first preferred embodiment is stopped. Also, in FIGS. 18A and 18B, the drawing with “A” is a cross-sectional view, and the drawing with “B” is a plan view. Note that, for ease of illustration, some elements of the semiconductor module 10 are not shown in the cross-sectional view A, and the heatsink 20 is additionally shown in the plan view B. Further, in FIGS. 18A and 18B, the heat dissipating material 30 is a member having fluidity, such as thermal grease or thermal putty. Further, referring to FIGS. 18A and 18B, the spacer 40 is described as a spacer formed with an adhesive that cures at a temperature equal to or higher than the heat-generating temperature of the semiconductor module 10. Note that, in FIG. 18B, the height of the heat dissipating material 30 at a time when the semiconductor module 10 according to the first preferred embodiment is stopped and the heat dissipating material 30 contracts is represented by L3, and the amount of shrinkage of the heat dissipating material 30 is represented by L4.

As illustrated in FIGS. 17B and 18B, the length L2 of the spacer 40 is smaller in the semiconductor device 2000 than in the semiconductor device 1000. Accordingly, as illustrated in FIG. 17B, when the semiconductor module 10 is stopped, the height L3 of the heat dissipating material 30 at a time when the heat dissipating material 30 contracts can be made greater in the semiconductor device 2000 than in the semiconductor device 1000, and thus, the shrinkage amount L4 at the time when the heat dissipating material 30 contracts can be reduced. Accordingly, in a case where a semiconductor device is mounted in the vertical direction, the increase in thermal resistance and the degradation in heat dissipation properties of the semiconductor module 10 can be further reduced.

### Third Preferred Embodiment.

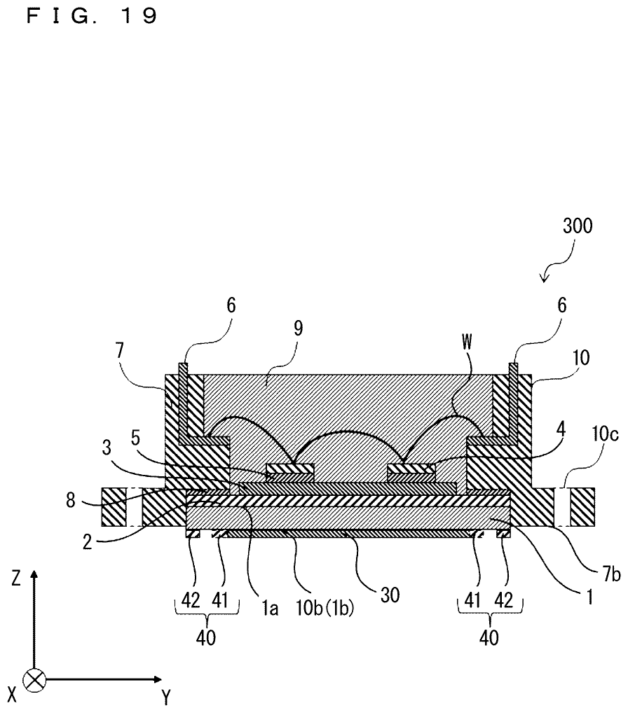

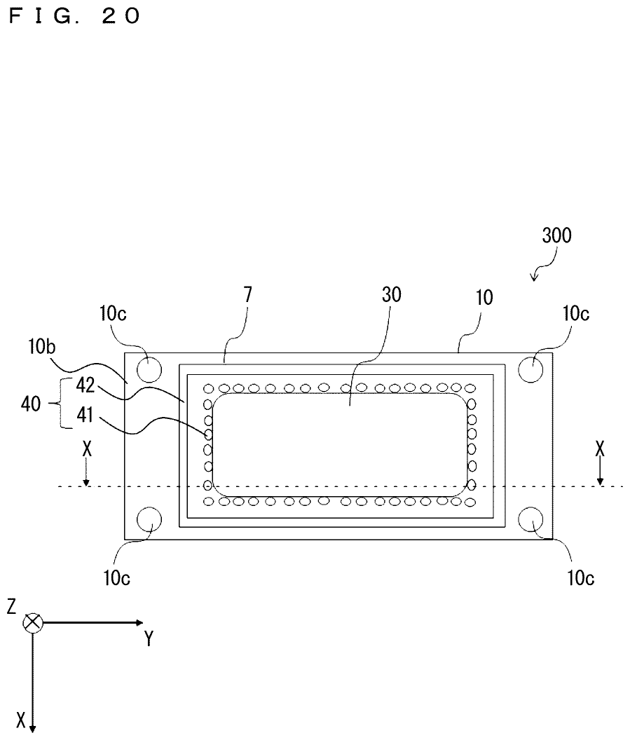

A semiconductor device 300 according to a third preferred embodiment is now described, with reference to FIGS. 19 and 20. FIG. 19 is a schematic cross-sectional view of the semiconductor device 300 according to the third preferred embodiment. FIG. 20 is a schematic plan view of the semiconductor device 300 according to the third preferred embodiment. Note that FIG. 19 shows a cross-section taken along the dot-and-dash line X-X defined in FIG. 20. Meanwhile, a schematic cross-sectional view of a semiconductor device 3000 that shows a state in which the semiconductor device 300 shown in FIGS. 19 and 20 is mounted on a heatsink 20 is not shown. Note that, in FIG. 19, fastening portions 10c are indicated by dotted lines.

As illustrated in FIGS. 19 and 20, in semiconductor device 300 according to the third preferred embodiment, a spacer 40 includes a first spacer 41 and a second spacer 42 located on the outer side of the first spacer 41 in a planar view. Also, as illustrated in FIG. 20, it is preferable that the first spacer 41 is provided so as to surround a heat dissipating material 30, and the second spacer 42 is provided so as to surround the first spacer 41. Further, as illustrated in FIG. 20, the second spacer 42 is continuously provided in a circumferential direction, but the first spacer 41 may be provided as dot-like members at intervals in the circumferential direction. Note that both the first spacer 41 and the second spacer 42 may be provided as dot-like members at intervals in the circumferential direction. Furthermore, each of the first spacer 41 and the second spacer 42 is provided in a rectangular shape in a planar view, but may have any appropriate shape. For example, each of the first spacer 41 and the second spacer 42 may be provided in a circular shape in a planar view. Also, the first spacer 41 may be provided in a circular shape in a planar view, and the second spacer 42 may be provided in a rectangular shape in a planar view. Alternatively, each of the first spacer 41 and the second spacer 42 may be provided in a trapezoidal shape in a planar view. Further, although both the first spacer 41 and the second spacer 42 are provided on the lower surface 1b of a heatsink plate 1 in FIGS. 19 and 20, both the first spacer 41 and the second spacer 42 may be provided on the lower surface 7b of a case member 7, or either one of the first spacer 41 and the second spacer 42 may be provided on the lower surface 1b of the heatsink plate 1 while the other is provided on the lower surface 7b of the case member 7.

Like the semiconductor device 1000, the semiconductor device 3000 includes the heatsink 20 and fastening members F.

The semiconductor devices 300 and 3000 of the third preferred embodiment are designed as described above. Like the semiconductor device 100 according to the first preferred embodiment, the semiconductor device 300 according to the third preferred embodiment has a configuration in which the spacer 40 is provided on the semiconductor module 10 at portions on the outer side of the heat dissipating material 30 in a planar view. Thus, when the semiconductor device 300 is mounted on the heatsink 20, and the semiconductor module 10 has started operating, the pumping out of the heat dissipating material 30 can be reduced, and the increase in thermal resistance and the degradation in heat dissipation properties of the semiconductor module 10 can be reduced. Also, like the semiconductor device 1000 according to the first preferred embodiment, the semiconductor device 3000 according to the third preferred embodiment has a configuration in which the spacer 40 is provided on the outer side of the heat dissipating material 30 in a planar view, between the semiconductor module 10 and the heatsink 20. Thus, when the semiconductor module 10 has started operating, the pumping out of the heat dissipating material 30 can be reduced, and the increase in thermal resistance and the degradation in heat dissipation properties of the semiconductor module 10 can be reduced.

Further, in semiconductor devices 300 and 3000 according to the third preferred embodiment, the spacer 40 includes the first spacer 41 and the second spacer 42 located on the outer side of the first spacer 41 in a planar view. With this arrangement, the heat dissipating material 30 can be further prevented from being pushed to the outside of the semiconductor device. The reason for that is described below.

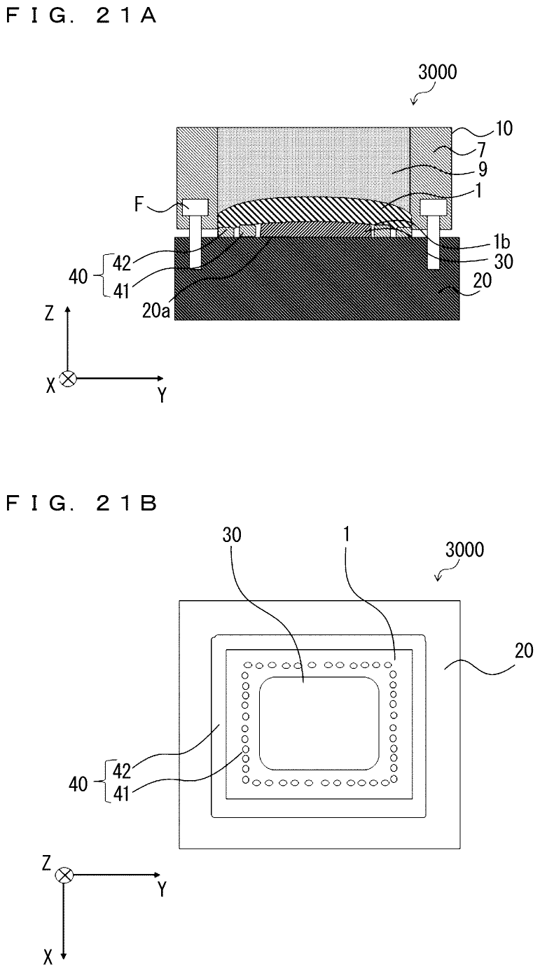

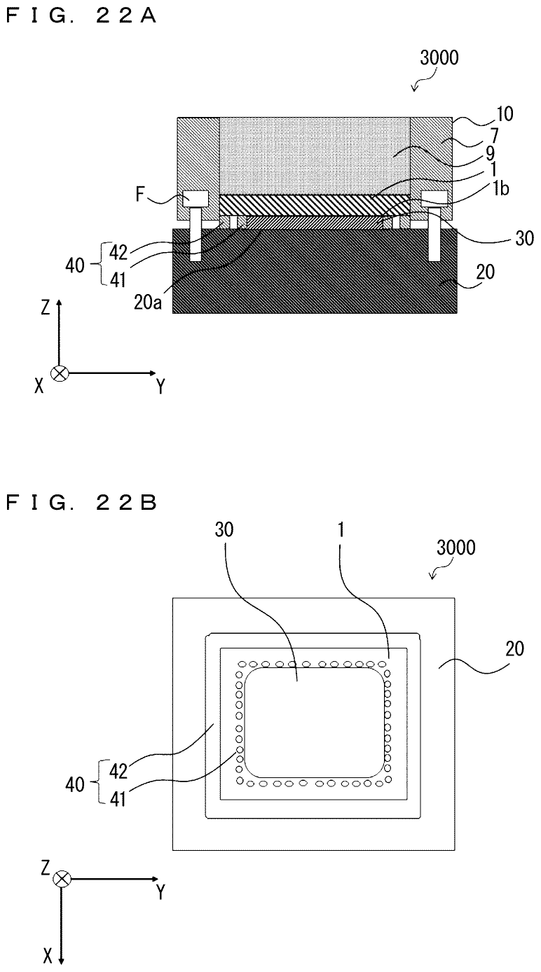

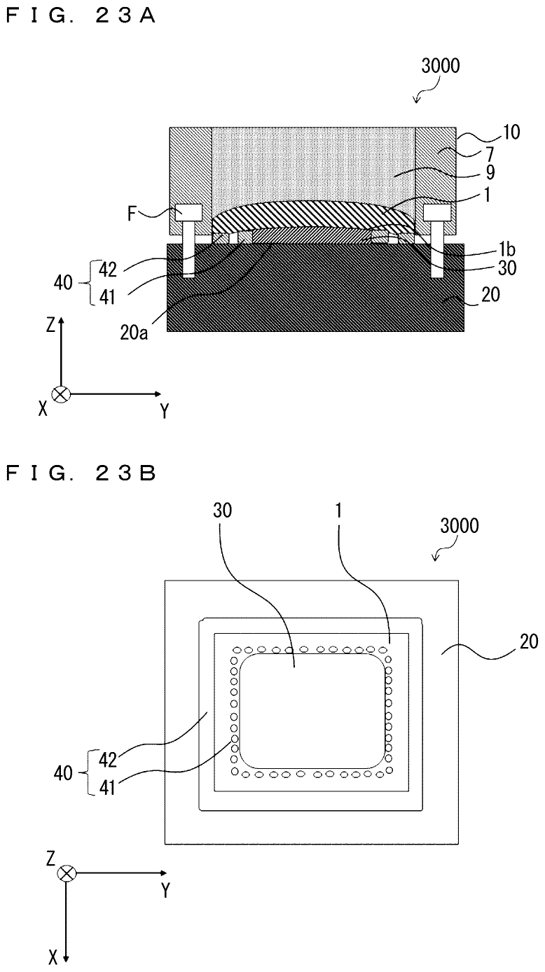

The semiconductor device 3000 according to the present preferred embodiment is shown in FIGS. 21A to 23B. FIGS. 21A and 21B are a schematic cross-sectional view and a schematic plan view of the semiconductor device 3000 at a time when the semiconductor module 10 according to the third preferred embodiment is attached to the heatsink 20. FIGS. 22A and 22B are a schematic cross-sectional view and a schematic plan view of the semiconductor device 3000 at a time when the semiconductor module 10 according to the third preferred embodiment has started operating. FIGS. 23A and 23B are a schematic cross-sectional view and a schematic plan view of the semiconductor device 3000 at a time when the semiconductor module 10 according to the third preferred embodiment is stopped. Also, among FIGS. 21A to 23B, each drawing with “A” is a cross-sectional view, and each drawing with “B” is a plan view. Note that, for ease of illustration, some elements of the semiconductor module 10 are not shown in each cross-sectional view A, and the heatsink 20 is additionally shown in each plan view B. Further, referring to FIGS. 21A to 23B, the spacer 40 is described as a spacer formed with an adhesive that cures at a temperature equal to or higher than the heat-generating temperature of the semiconductor module 10.

As illustrated in FIGS. 21A and 21B, when the semiconductor module 10 is attached to the heatsink 20, the lower surface 1b of the heatsink plate 1 is deformed so as to warp in a direction away from the upper surface 20a of the heatsink 20, as in FIGS. 7A and 7B.

As illustrated in FIGS. 22A and 22B, when the semiconductor module 10 is operating, the lower surface 1b of the heatsink plate 1 is deformed in a direction toward the upper surface 20a of the heatsink 20, as in FIGS. 8A and 8B. As illustrated in FIGS. 22A and 22B, in conjunction with the deformation of the heatsink plate 1 and the thermal expansion of the heat dissipating material 30, the heat dissipating material 30 wets and spreads in an outer circumferential direction. As illustrated in FIGS. 22A and 22B, in the semiconductor device 3000 according to the third preferred embodiment, the first spacer 41 is provided on the outer side of the heat dissipating material 30 in a planar view, and the second spacer 42 is provided on the outer side of the first spacer 41 in a planar view. Therefore, even in a case where the heatsink plate 1 is deformed during an operation of the semiconductor module 10, both the first spacer 41 and the second spacer 42 function as a stopper. Accordingly, the heat dissipating material 30 can be first prevented from moving to the outer side of the first spacer 41 by the first spacer 41. Even if the heat dissipating material 30 passes through the first spacer and moves to the outer side of the first spacer 41, the heat dissipating material 30 can be prevented from moving to the outer side of the second spacer 42 by the second spacer 42. Thus, the occurrence of pumping out by which the heat dissipating material 30 interposed between the heatsink plate 1 and the heatsink 20 is pushed out to the periphery of the semiconductor device 3000 can be reduced. Note that, in a case where each of the first spacer 41 and the second spacer 42 is formed with an adhesive that cures at a temperature equal to or higher than the heat-generating temperature of the semiconductor module 10, it is possible to further reduce the occurrence of pumping out by which the heat dissipating material 30 interposed between the heatsink plate 1 and the heatsink 20 is pushed out to the periphery of the semiconductor device 3000 as described above. Also, as described above, the first spacer 41 may be provided as dot-like members at intervals in the circumferential direction. With this arrangement, the amount of use of the first spacer 41 can be reduced compared with that in a case where the first spacer 41 is continuously provided in the circumferential direction, and thus, the manufacturing cost of semiconductor devices can be lowered.

As illustrated in FIGS. 23A and 23B, when the semiconductor module 10 is stopped, the lower surface 1b of the heatsink plate 1 is deformed so as to warp in a direction away from the upper surface 20a of the heatsink 20, as in FIGS. 10A and 10B. As described above, during an operation of the semiconductor module 10, the heat dissipating material 30 can be prevented from moving to the outer sides of the first spacer 41 and the second spacer 42 by the first spacer 41 and the second spacer 42, and the occurrence of pumping out by which the heat dissipating material 30 is pushed out to the periphery of the semiconductor device 3000 can be reduced. Thus, even in a case where the heatsink plate 1 is deformed and the heat dissipating material 30 interposed between the heatsink plate 1 and the heatsink 20 contracts when the semiconductor module 10 is stopped, the appearance of voids B in the heat dissipating material 30 can be further reduced. Accordingly, the increase in thermal resistance and the degradation in heat dissipation properties of the semiconductor module 10 can be further reduced.

Note that the configurations described in the above preferred embodiments are examples of the contents of the present disclosure, and can be combined with some other known technology. Also, the preferred embodiments can be combined with each other, and the modifications can be combined with each other. Further, some of the configurations can be omitted or modified without departing from the gist of the present disclosure.

In the following, various modes of the present disclosure are collectively described as Appendixes.

### (Appendix 1)

A semiconductor device comprising:
a semiconductor module having a heatsink plate placed on a lower surface side;
a heatsink having the semiconductor module mounted on an upper surface;
a heat dissipating material interposed between the heatsink plate and the heatsink; and
a spacer placed between the semiconductor module and the heatsink, wherein
the spacer is placed on an outer side of the heat dissipating material in a planar view.

### (Appendix 2)

The semiconductor device according to Appendix 1, wherein the spacer is provided to surround the heat dissipating material in a planar view.

### (Appendix 3)

The semiconductor device according to Appendix 1 or 2, wherein the spacer is provided to be in contact with a lower surface of the semiconductor module and an upper surface of the heatsink.

### (Appendix 4)

The semiconductor device according to Appendix 3, wherein the spacer is formed with an adhesive that cures at a temperature equal to or higher than a heat-generating temperature of the semiconductor module.

### (Appendix 5)

The semiconductor device according to Appendix 4, wherein, when the adhesive has cured, a height of the adhesive and a height of the heat dissipating material are the same.

### (Appendix 6)

The semiconductor device according to any one of Appendixes 1 to 5, wherein the spacer is provided to be in contact with the heatsink plate.

### (Appendix 7)

The semiconductor device according to any one of Appendixes 1 to 6, wherein
the semiconductor module includes a case member on an outer periphery, and
the spacer is provided to be in contact with the case member.

### (Appendix 8)

The semiconductor device according to Appendix 7, wherein
an inner wall of the case member and a side surface of the heatsink plate are provided, with a gap being formed between the inner wall and the side surface, and
the spacer is placed in the gap.

### (Appendix 9)

The semiconductor device according to Appendix 7, wherein
the case member has a recessed portion in a lower surface, and
the spacer is placed in the recessed portion.

### (Appendix 10)

The semiconductor device according to Appendix 2, wherein the spacer is provided in a trapezoidal shape in a planar view.

### (Appendix 11)

The semiconductor device according to any one of Appendixes 1 to 10, wherein
the spacer includes:
   a first spacer; and
   a second spacer provided on an outer side of the first spacer in a planar view.

### (Appendix 12)

A semiconductor device mounted on a heatsink, the semiconductor device comprising:
a semiconductor module having a heatsink plate placed on a lower surface side;
a heat dissipating material placed on a lower surface of the heatsink plate; and
a spacer provided on the semiconductor module, wherein
the spacer is placed on an outer side of the heat dissipating material in a planar view.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor module having a heatsink plate placed on a lower surface side;
a heatsink having the semiconductor module mounted on an upper surface;
a heat dissipating material interposed between the heatsink plate and the heatsink; and
a spacer placed between the semiconductor module and the heatsink, wherein
the spacer is placed on an outer side of the heat dissipating material in a planar view.

2. The semiconductor device according to claim 1, wherein the spacer is provided to surround the heat dissipating material in a planar view.

3. The semiconductor device according to claim 1, wherein the spacer is provided to be in contact with a lower surface of the semiconductor module and an upper surface of the heatsink.

4. The semiconductor device according to claim 3, wherein the spacer is formed with an adhesive that cures at a temperature equal to or higher than a heat-generating temperature of the semiconductor module.

5. The semiconductor device according to claim 4, wherein, when the adhesive has cured, a height of the adhesive and a height of the heat dissipating material are the same.

6. The semiconductor device according to claim 1, wherein the spacer is provided to be in contact with the heatsink plate.

7. The semiconductor device according to claim 1, wherein
the semiconductor module includes a case member on an outer periphery, and
the spacer is provided to be in contact with the case member.

8. The semiconductor device according to claim 7, wherein
an inner wall of the case member and a side surface of the heatsink plate are provided, with a gap being formed between the inner wall and the side surface, and
the spacer is placed in the gap.

9. The semiconductor device according to claim 7, wherein
the case member has a recessed portion in a lower surface, and
the spacer is placed in the recessed portion.

10. The semiconductor device according to claim 2, wherein the spacer is provided in a trapezoidal shape in a planar view.

11. The semiconductor device according to claim 1, wherein
the spacer includes:
a first spacer; and
a second spacer provided on an outer side of the first spacer in a planar view.

12. A semiconductor device mounted on a heatsink, the semiconductor device comprising:
a semiconductor module having a heatsink plate placed on a lower surface side;
a heat dissipating material placed on a lower surface of the heatsink plate; and
a spacer provided on the semiconductor module, wherein
the spacer is placed on an outer side of the heat dissipating material in a planar view.
